(19) United States
(12) Patent Application Publication
(10) Pub. No.: US 2012/0315453 A1
(43) Pub. Date: Dec. 13, 2012

(54) COATING LAYER STRUCTURE OF BASIC MATERIAL OF MOLD

(75) Inventors: Sung Chul Cha, Seoul (KR); Ju Chul Kim, Ulsan (KR); Seung Taik Oh, Yongin (KR); Kun Uk Park, Hwaseong-si (KR); Doo Hwan Lee, Suwon (KR); Hyun Dal Park, Suwon (KR); Ho Young Kong, Ulsan (KR)

(73) Assignee: Hyundai Motor Company, Seoul (KR)

(21) Appl. No.: 13/312,939

(22) Filed: Dec. 6, 2011

(30) Foreign Application Priority Data
Jun. 10, 2011 (KR) 10-2011-0056164

(51) Int. Cl. B32B 7/02; B32B 3/00; B32B 9/00; C23C 16/34; C23C 16/50

(52) U.S. Cl. 428/216; 427/569; 428/698; 428/336

(57) ABSTRACT

This invention relates to a coating layer structure of a basic material of a mold, which exhibits good adhesion between a coating material and a basic material and does not cause cracking when coated. Such a coating layer structure includes an ion nitriding layer formed at the surface of the basic material, a middle coating layer formed on the ion nitriding layer using AlTiCrN, AlCrSiN, AlTiSiN, or AlTiCrSiN, and a surface coating layer formed on the middle coating layer using AlTiCrCN, AlCrSiCN, AlTiSiCN, or AlTiCrSiCN.

### CROSS-REFERENCE TO RELATED APPLICATIONS

This application claims under 35 U.S.C. §119(a) priority to Korean Application No. 10-2011-0056164, filed on Jun. 10, 2011, the disclosure of which is incorporated herein by reference in its entirety.

### BACKGROUND OF THE INVENTION

1. Field of the Invention

The present invention relates to a coating layer structure, particularly a coating layer structure which coats a basic material of a mold. More particularly, the present invention relates to such a coating layer structure which provides good adhesion between a coating material and a basic material and which does not cause cracking when coated.

2. Description of the Related Art

Molds, such as molds for the steel sheets of automobiles, undergo much stress when used, which undesirably shortens their lifetime. In attempt to extend this lifetime, the surfaces of the mold are typically coated. The type of coating material used varies depending on the end use and desired properties, including imparting wear resistance, etc.

FIG. 1 is a flowchart showing a conventional process of coating a basic material of a mold. With reference to FIG. 1, the conventional method of coating the basic material of a mold includes plasma nitriding treatment (S110) and PVD (Physical Vapor Deposition) coating (S120).

In plasma nitriding treatment (S110), nitrogen gas is fed into a reaction chamber in which a basic material has been loaded, after which the fed nitrogen gas is ionized. The nitrogen particles penetrate and diffuse into the surface of the basic material thus increasing the thickness of a curing layer. As a result, the hardness of the basic material may increase, appropriate toughness may be imparted, and the force of adhesion between thin films may be enhanced.

In PVD coating (S120), the surface of the basic material is coated with a desired coating material using PVD.

However, the conventional coating layer structure of a metal basic material has a low force of adhesion between the coating layer and the basic material, undesirably resulting in easy separation and leading to poor hardness and a low coefficient of friction.

### SUMMARY OF THE INVENTION

Accordingly, the present invention has been made keeping in mind the above problems encountered in the related art. An object of the present invention is to provide a coating layer structure of a basic material of a mold, which provides a high force of adhesion between a coating material and a basic material and which does not cause cracking when coated.

An aspect of the present invention provides a coating layer structure of a basic material of a mold, comprising an ion nitriding layer formed at the surface of the basic material, a middle coating layer formed on the ion nitriding layer, and a surface coating layer formed on the middle coating layer. In this aspect, the middle coating layer and surface coating layer may be formed using, for example, AlTiCrN, AlCrSiN, AlTiSiN, or AlTiCrSiN.

In this aspect, the ion nitriding layer may be formed by subjecting the surface of the basic material to plasma treatment. In various embodiments, the ion nitriding layer may be formed to have a suitable thickness, such as a thickness of about 80˜120 μm, the middle coating layer and the surface coating layer may be formed to have a suitable thickness, such as a thickness of about 4˜16 μm, and the surface coating layer may be formed to have a suitable thickness, such as a thickness of about 2 μm or less. For example, the thickness of the surface coating layer can be any value greater than 0, such as about 0.05 μm or greater, about 0.1 μm or greater, about 0.2 μm or greater, about 0.3 μm or greater, about 0.4 μm or greater, about 0.5 μm or greater, about 0.6 μm or greater, about 0.7 μm or greater, about 0.8 μm or greater, etc., ranging up to about 2 μm.

In this aspect, the coating layer structure may further comprise a TiC coating layer on the surface of the surface coating layer. The TiC coating layer may be formed to have a suitable thickness, for example a thickness of about 0.1˜0.3 μm.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a flowchart showing a conventional process of coating a basic material of a mold;

FIG. 2 is a schematic view showing a coating layer structure of a basic material of a mold according to an embodiment of the present invention;

FIG. 3 is a view specifically showing the coating layer of FIG. 2; and

FIG. 4 is a photograph showing the coating layer structure of the basic material of a mold, according to the embodiment of the present invention.

### DESCRIPTION OF SPECIFIC EMBODIMENTS

Hereinafter, preferred embodiments of the present invention are described with reference to the accompanying drawings.

Unless specifically stated or obvious from context, as used herein, the term “about” is understood as within a range of normal tolerance in the art, for example within 2 standard deviations of the mean. About can be understood as within 10%, 9%, 8%, 7%, 6%, 5%, 4%, 3%, 2%, 1%, 0.5%, 0.1%, 0.05%, or 0.01% of the stated value. Unless otherwise clear from context, all numerical values provided herein are modified by the term about.

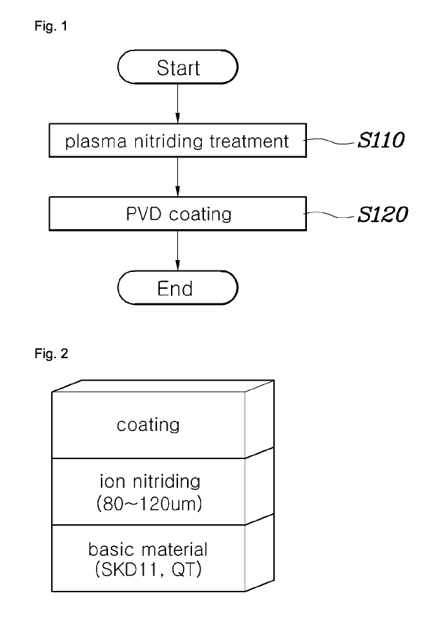

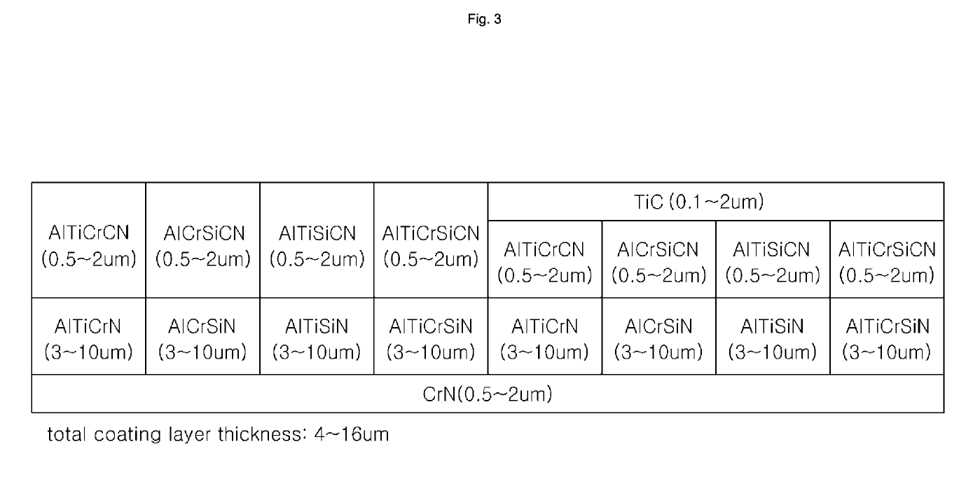

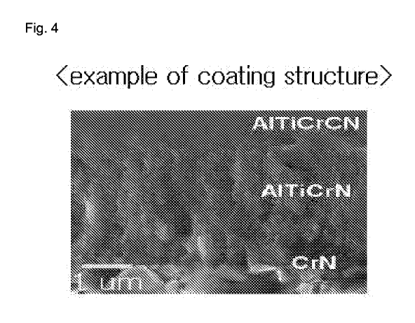

FIG. 2 schematically shows the coating layer structure of a basic material of a mold according to an embodiment of the present invention, FIG. 3 specifically shows the coating layer of FIG. 2, and FIG. 4 is a photograph showing the coating layer structure of the basic material of a mold, according to an embodiment of the present invention.

As shown in FIGS. 2 to 4, the coating layer structure of a basic material of a mold according to an embodiment of the present invention includes an ion nitriding layer formed at the surface of the basic material, followed by a middle coating layer and a surface coating layer. The ion nitriding layer may be formed by subjecting the surface of the basic material to plasma treatment. The middle coating layer and surface coating layer may be formed by coating the surface of the ion nitriding layer with a carbon-doped nitride. As such, the basic material of a mold may be formed into a mold that undergoes large amounts of stress when used, for an automobile steel sheet, etc. Further, the basic material of a mold according to the present invention may also include other basic materials used in molds.

According to embodiments of the present invention, the ion nitriding layer may be formed by loading the basic material for a mold into a reaction chamber, and subjecting the surface of the basic material to plasma nitriding treatment. AS such, nitrogen activated with plasma penetrates and diffuses into the basic material, thus forming the ion nitriding layer.

According to an exemplary embodiment, the formation of such an ion nitriding layer may be carried out as follows.

Prior to loading the basic material, the inside of the reaction chamber is made vacuous, after which hydrogen (H2) gas and argon (Ar) gas are fed into the reaction chamber, so that sputtering may be carried out. The basic material is then loaded into the reaction chamber and sputtering carried out to clean the surface of the basic material, and to make the surface state of the basic material unstable which facilitates penetration and diffusion of nitrogen gas upon subsequent nitriding treatment.

Subsequently, hydrogen (H2) gas and nitrogen (N2) gas are fed into the reaction chamber and voltage is applied thereto, so that nitriding treatment can be carried out. The nitriding treatment may be carried out for a suitable time, for example about 8˜15 hours under the condition of nitrogen being activated in the reaction chamber. The process temperature may be suitably elevated, for example, about 460˜490° C. when forming the ion nitriding layer.

The total thickness of the ion nitriding layer and the compound layer formed towards the inside of the basic material from the surface thereof may be about 80˜120 μm. If the total thickness of the ion nitriding layer and the compound layer formed inwards the surface of the basic material is too thin, for example less than about 80 μm, it becomes difficult to achieve the necessary hardness and toughness of the basic material and to enhance the force of adhesion between the basic material and the coating layer. As the total thickness of the ion nitriding layer and the compound layer becomes larger, the above effects (i.e. suitable hardness, toughness and adhesion) may be efficiently exhibited. However, if the above thickness from the surface of the basic material is too large, for example exceeding about 120 μm, the resulting layer becomes difficult to penetrate and diffuse activated nitrogen.

After the plasma nitriding treatment has been completed, a nitride thin-film that is fine and hard, such as a CrN layer, is selectively formed on the surface of the ion nitriding layer. The nitride thin-film is thus formed so as to impart impact resistance to the surface of the basic material.

On top of the nitride thin-film, a coating layer is formed. In particular, the coating layer is formed by coating the surface of the ion nitriding layer with a suitable material, such as carbon-doped nitride.

It is understood that the type of coating material may vary depending on the end uses and desired properties imparted thereby, including, for example, imparting hardness, corrosion resistance, wear resistance, etc. As such, any suitable coating material may be used and may be selected by taking into consideration these desired properties and end uses.

For example, because a mold for an automobile steel sheet requires high hardness, high wear resistance, and high heat resistance, a metal nitride compound such as AlTiCrN, AlCrSiN, AlTiSiN, AlTiCrSiN, etc., may suitably be adopted.

According to various embodiments, the coating layer made of a metal nitride compound may be formed using CVD (Chemical Vapor Deposition) or PVD. Also, in order to produce high-density plasma to form coating material nanoparticles and achieve a high-rate coating, arc, HIPIMS (High Power Impulse Magnetron Sputtering), ICP (inductive Coupled Plasma), etc., may be applied.

The middle coating layer and the surface coating layer may be formed to have a suitable thickness to impart desired properties, for example, a thickness of about 4˜16 μm. If the thickness of the middle coating layer and the surface coating layer are too small, for example less than about 4 μm, then insufficient hardness and wear resistance are imparted to the basic material by the coating. On the other hand, if the thickness of the middle coating layer and the surface coating layer is too large, for example exceeding about 16 μm, when a fine pattern is formed on the basic material, it may become difficult to form a coating layer having a uniform thickness throughout the basic material due to such a fine pattern and the coating cost may excessively increase.

According to embodiments of the present invention, the surface coating layer may be formed by doping the surface of the middle coating layer (which is coated with a metal nitride compound) with carbon, thus forming a metal carbonitride compound. In particular, the surface of the middle coating layer made of a metal nitride compound is doped with carbon to produce a metal carbonitride compound, thereby increasing a coefficient of friction and wear resistance. As such, carbon is doped using methane, acetylene, and benzene gas, and the metal nitride compound is doped together with nitrogen gas.

The metal nitride compound doped with carbon and nitrogen includes, for example, AlTiCrCN, AlCrSiCN, AlTiSiCN, AlTiCrSiCN, having low friction and superior heat resistance and wear resistance. The thickness of the surface coating layer doped with carbon is, for example, about 2 μm or less.

In some embodiments, in order to further maximizing the property of low friction, a TiC layer may be further applied on the surface of the surface coating layer doped with carbon. The thickness of the TiC layer can vary to enhance this low friction and, for example, can be about 0.1˜3 μm thick.

Table 1 below shows the properties of the basic material of a mold according to examples of the present invention (the properties of the coating material being specified in the Table), and further shows these properties compared to those of the specified comparative examples.

TABLE 1
Properties of Examples and Comparative Examples

| | | | | Coefficient | | |
|---|---|---|---|---|---|---|
| | | | | of | | Oxidation |
| | | | Thickness | Friction | Hardness | Temp. |
| | Coating material | Processing | (μm) | (CoF Dry) | (HV) | (° C.) |
| Examples | AlTiCrN + AlTiCrCN | PVD-Arc | 2.04 | 0.25 | 3.260 | 870 |
| | AlCrSiN + AlCrSiCN | PVD-Arc | 1.82 | 0.15 | 3.027 | 750 |
| | AlTiSiN + AlTiSiCN | PVD-Arc | 1.91 | 0.13 | 3.165 | 1000 |
| | AlTiCrSiN + AlTiCrSiCN | PVD-Arc | 2.12 | 0.22 | 3.743 | 920 |
| | AlTiCrN + AlTiCrCN + TiC | PVD-Arc | 1.80 + 1.12 | 0.15 | 3.034 | 650 |
| | AlCrSiN + AlCrSiCN + TiC | PVD-Arc | 1.72 + 1.27 | 0.11 | 3.042 | 670 |
| | AlTiSiN + AlTiSiCN + TiC | PVD-Arc | 1.75 + 1.16 | 0.09 | 2.952 | 660 |
| | AlTiCrSiN + AlTiCrSiCN + TiC | PVD-Arc | 1.77 + 1.32 | 0.10 | 3.067 | 670 |
| Comparative | VC | TD | 8.4 | 0.571 | 2.634 | 500 |
| Examples | | Treatment | | | | |
| <Conventional | TiAlN | PVD-Arc | 11 | 0.56 | 3.000 | 810 |
| Materials> | AlTiCrN + MoS2 | PVD-Arc + | 13 | 0.471 | 3.150 | 900(450) |
| | | Spraying | | (initially | | |
| | | | | 0.12) | | |

1. Coefficient of Friction (Wear Resistance)

As shown in Table 1, the coefficients of friction of the comparative examples were 0.571, 0.56, and 0.471 (initially 0.12), which demonstrates that a large amount of occurred. However, in the examples in accordance with the present invention, the coefficients of friction were 0.25, 0.15, 0.13, 0.22, 0.15, 0.11, 0.09, and 0.10, which are significantly lower than those of the comparative examples. As such, it is demonstrated that a comparatively small amount of wear occurred in the examples according to the present invention. Thus, the examples (present invention) clearly demonstrated lower coefficients of friction and superior wear resistance, as compared to the comparative examples.

2. Hardness

As shown in Table 1, hardness of the comparative examples was 2.634 HV, 3.000 HV, and 3.150 HV, whereas hardness of the examples (present invention) was 3.260 HV, 3.027 HV, 3.165 HV, 3.743 HV, 3.034 HV, 3.042 HV, 2.952 HV, and 3.067 HV. Thus, it is clearly demonstrated that higher hardness was achieved in the examples (present invention) compared to the comparative examples.

Therefore, when the coating layer structure of the basic material of a mold according to the embodiments of the present invention is provided by plasma nitriding treatment, followed by coating the surface of the ion nitriding layer with a carbon-doped nitride, high hardness and enhanced wear resistance are achieved.

As described hereinbefore, the present invention provides a coating layer structure of a basic material of a mold. According to the present invention, the coating layer structure of the basic material according to the embodiments of the present invention exhibits high hardness and enhanced wear resistance, particularly by coating the surface of the ion nitriding layer with a carbon-doped nitride after plasma nitriding treatment.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A coating layer structure of a basic material of a mold, comprising:
an ion nitriding layer formed at a surface of the basic material;
a middle coating layer formed on the ion nitriding layer using AlTiCrN, AlCrSiN, AlTiSiN, or AlTiCrSiN; and
a surface coating layer formed on the middle coating layer using AlTiCrCN, AlCrSiCN, AlTiSiCN, or AlTiCrSiCN.

2. The coating layer structure of claim 1, wherein the ion nitriding layer is formed by subjecting the surface of the basic material to plasma treatment, the ion nitriding layer having a thickness of about 80˜120 μm.

3. The coating layer structure of claim 2, wherein the middle coating layer and the surface coating layer have a total thickness of about 4˜16 μm.

4. The coating layer structure of claim 3, and the thickness of the surface coating layer is about 2 μm or less.

5. The coating layer structure of claim 1, further comprising a TiC coating layer on a surface of the surface coating layer, the TiC coating layer having a thickness of about 0.1˜0.3 μm.

6. A method for forming a coating layer structure of a basic material of a mold, comprising:
forming an ion nitriding layer formed at a surface of the basic material;
forming a middle coating layer on the ion nitriding layer using AlTiCrN, AlCrSiN, AlTiSiN, or AlTiCrSiN; and
forming a surface coating layer on the middle coating layer using AlTiCrCN, AlCrSiCN, AlTiSiCN, or AlTiCrSiCN.

7. The method of claim 6, wherein the step of forming the ion nitriding layer comprises subjecting the surface of the basic material to plasma treatment.

8. The method of claim 6, wherein the ion nitriding layer is formed to have a thickness of about 80˜120 μm, and the middle coating layer and the surface coating layer are formed to have a total thickness of about 4˜16 μm.

9. The method of claim 6, wherein the step of forming the middle coating layer and surface coating layer comprises coating the surface of the ion nitriding layer with a carbon-doped nitride.

10. The method of claim 6 further comprising forming a TiC coating layer on a surface of the surface coating layer, the TiC coating layer having a thickness of about 0.1˜0.3 μm.
